(19) United States
(12) Patent Application Publication
(10) Pub. No.: US 2017/0222022 A1
(43) Pub. Date: Aug. 3, 2017

(54) SEMICONDUCTOR DEVICE WITH COMPOSITE TRENCH AND IMPLANT COLUMNS

(71) Applicant: Vishay-Siliconix, Santa Clara, CA (US)

(72) Inventors: Deva PATTANAYAK, Saratoga, CA (US); Sandeep AGGARWAL, Pune (IN)

(21) Appl. No.: 15/486,752

(22) Filed: Apr. 13, 2017

Related U.S. Application Data
(62) Division of application No. 14/659,415, filed on Mar. 16, 2015.
(60) Provisional application No. 62/015,962, filed on Jun. 23, 2014.

(51) Int. Cl. H01L 29/66; H01L 21/225; H01L 29/78; H01L 29/06; H01L 29/10

(52) U.S. Cl. CPC H01L 29/66712; H01L 29/0634; H01L 29/1095; H01L 29/7802; H01L 21/2254

(57) ABSTRACT

A metal insulator semiconductor field effect transistor (MISFET) such as a super junction metal oxide semiconductor FET with high voltage breakdown is realized by, in essence, stacking a relatively low aspect ratio column (trenches filled with dopant, e.g., p-type dopant) on top of a volume or volumes formed by implanting the dopant in lower layers. Together, the low aspect ratio column and the volume(s) form a continuous high aspect ratio column.

### RELATED U.S. APPLICATIONS

This application is a continuation (divisional) application of U.S. patent application Ser. No. 14/659,415, filed Mar. 16, 2015, by D. Pattanayak et al., which claims priority to the U.S. Provisional Application No. 62/015,962, entitled “Semiconductor Device with Composite Trench and Implant Columns,” filed on Jun. 23, 2014, which are both hereby incorporated by reference in their entirety.

### BACKGROUND

Breakdown voltage provides an indication of the ability of a semiconductor device (e.g., a metal oxide semiconductor field effect transistor (MOSFET) device) to withstand breakdown under reverse voltage conditions. Devices such as super junction (SJ) MOSFETs increase breakdown voltage using alternating p-type and n-type regions at the active regions of the device. When the charges in the alternating p-type and n-type regions in a SJ MOSFET are balanced (the charges in the p-type regions, Qₚ, are equal to the charges in the n-type regions, Qₙ), then breakdown voltage is at its peak value, thereby enabling the device to better withstand breakdown.

N-channel SJ MOSFETs employ buried p-type column regions in the drift region. Breakdown voltage increases with column length; the greater the aspect ratio of the column, the higher the breakdown voltage. For example, for a 600V breakdown voltage, a trench depth of 40 microns and a trench diameter of four microns (an aspect ratio equal of 10) are desired. One way to form the p-type column regions is to etch a trench in an n-type epitaxial layer and then fill the trench with p-type doped silicon. However, it is difficult to achieve the high aspect ratio trench desired for high performance high voltage MOSFETs using this type of process. For example, nearly vertical column walls are desirable, but it is difficult to achieve nearly vertical walls when etching a high aspect ratio trench.

Even if a high aspect ratio trench is formed, it can still be problematic because it is also difficult to fill such a trench with p-type doped silicon, because the mouth of the trench has the tendency to be blocked as the trench is being filled, shutting off or occluding access to the deeper parts of the trench.

Thus, for these practical reasons, it is desirable to limit the depth of the trench so that the aspect ratio is manageable. For example, for a trench diameter of four microns, the trench depth can be limited to 20 microns, resulting in an aspect ratio of only five. However, as noted above, this reduces the breakdown voltage relative to a trench with a larger aspect ratio.

### SUMMARY

In overview, embodiments according to the present invention realize metal insulator semiconductor FETs (MISFETs) such as SJ MOSFETs with high voltage breakdown by, in essence, stacking a relatively low aspect ratio column (trenches filled with dopant, e.g., p-type dopant) on top of a volume or volumes formed by implanting the dopant in lower layers. Together, the low aspect ratio column and the volume(s) form a continuous high aspect ratio column, which may be referred to herein as a composite trench and implant column.

More specifically, in one embodiment, in an n-channel device, an n-type layer is formed (e.g., over a substrate layer), and p-type dopant is implanted to form a first p-type region in that layer. This process can be optionally repeated to form one or more additional p-type regions that are aligned vertically with the first region. Each p-type region is then thermally driven to diffuse the p-type dopant, forming a larger volume of p-type dopant; in essence, each region is diffused to form a larger volume of p-type dopant that is in contact with any adjacent, aligned volume(s) similarly formed. Then, another n-type layer (an epitaxial layer) is formed over the volume(s). A trench is etched through that layer, where the trench is aligned with the volume(s) and abuts (is in contact with) the uppermost volume. The trench is filled with p-type dopant, thus forming a continuous composite trench and implant column of p-type dopant consisting of the filled trench and the underlying volume(s). The aspect ratio of the composite trench and implant column is greater than the aspect ratio of just the trench portion.

The breakdown voltage of this type of device is scalable by changing the number of volumes and/or by changing the length of the trench portion. Also, because the trench portion still has a relatively low aspect ratio, the dopant filling the trench will be more evenly distributed. Furthermore, because of inherent voids in the filled trenches, the device's reverse recovery charge (Qrr) will be beneficially lower. Moreover, the thermal cycle experienced by the trench portion of the composite trench and implant column will be reduced so that there will be less diffusion of the dopant from the trench portion into the surrounding epitaxial layer. In addition, the cost of forming composite trench and implant columns is lower than conventional approaches for forming high aspect ratio columns.

In general, embodiments according to the invention achieve high aspect ratio columns, and therefore high breakdown voltage, in devices such as SJ MOSFETs, while overcoming the shortcomings associated with conventional processes.

These and other objects and advantages of embodiments according to the present invention will be recognized by one skilled in the art after having read the following detailed description, which are illustrated in the various drawing figures.

### BRIEF DESCRIPTION OF THE DRAWINGS

The accompanying drawings, which are incorporated in and form a part of this specification, illustrate embodiments of the invention and, together with the description, serve to explain the principles of the invention. Like numbers denote like elements throughout the drawings and specification.

FIG. 1 is a flowchart of a method for fabricating a semiconductor device (e.g., a super junction power MOSFET device) in an embodiment according to the present invention.

FIGS. 2, 3, 4, 5, 6, 7, 8, 9, and 10 are cross-sectional views showing elements of a semiconductor device at various stages of fabrication, in embodiments according to the present invention.

FIG. 11 is a cross-sectional view of a portion of a semiconductor device (e.g., an SJ MOSFET device) in an embodiment according to the present invention.

FIG. 12 is a flowchart of a method for fabricating a semiconductor device in an embodiment according to the present invention.

### DETAILED DESCRIPTION

In the following detailed description of the present invention, numerous specific details are set forth in order to provide a thorough understanding of the present invention. However, it will be recognized by one skilled in the art that the present invention may be practiced without these specific details or with equivalents thereof. In other instances, well-known methods, procedures, components, and circuits have not been described in detail as not to unnecessarily obscure aspects of the present invention.

The figures are not drawn to scale, and only portions of the structures, as well as the various layers that form those structures, may be shown in the figures.

As used herein, the letter “n” refers to an n-type dopant and the letter “p” refers to a p-type dopant. A plus sign “+” or a minus sign “−” is used to represent, respectively, a relatively high or relatively low concentration of the dopant. For example, “n+” would indicate a higher concentration of n-type dopant than “n,” which would indicate a higher concentration of n-type dopant than “n−.”

The term “channel” is used herein in the accepted manner. That is, current moves within a FET in a channel, from the source connection to the drain connection. A channel can be made of either n-type or p-type semiconductor material; accordingly, a FET is specified as either an n-channel or p-channel device. The disclosure is presented in the context of an n-channel device, specifically an n-channel SJ MOSFET; however, embodiments according to the present invention are not so limited. That is, the features described herein can be utilized in a p-channel device. The disclosure can be readily mapped to a p-channel device by substituting, in the discussion, n-type dopant and materials for corresponding p-type dopant and materials, and vice versa.

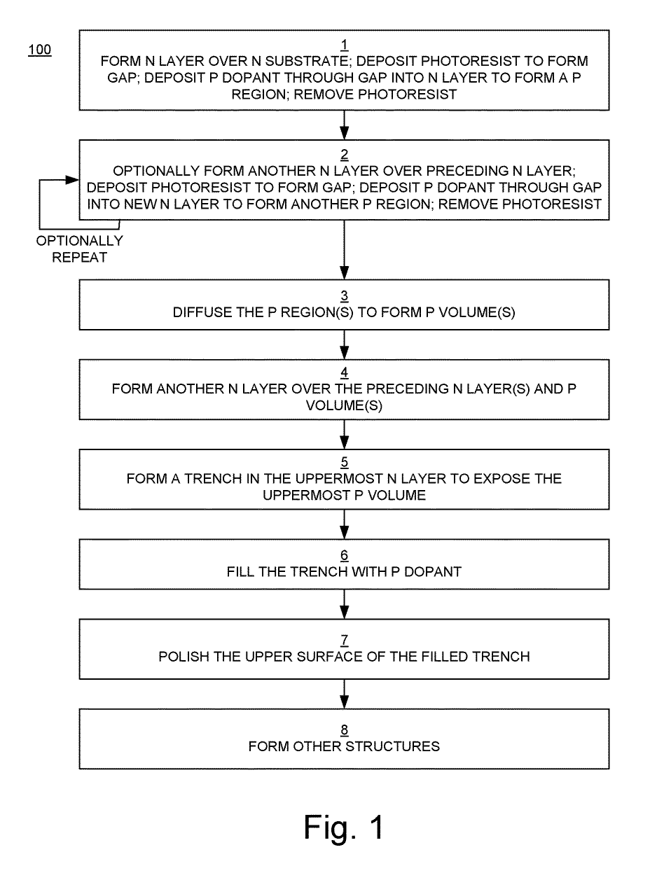

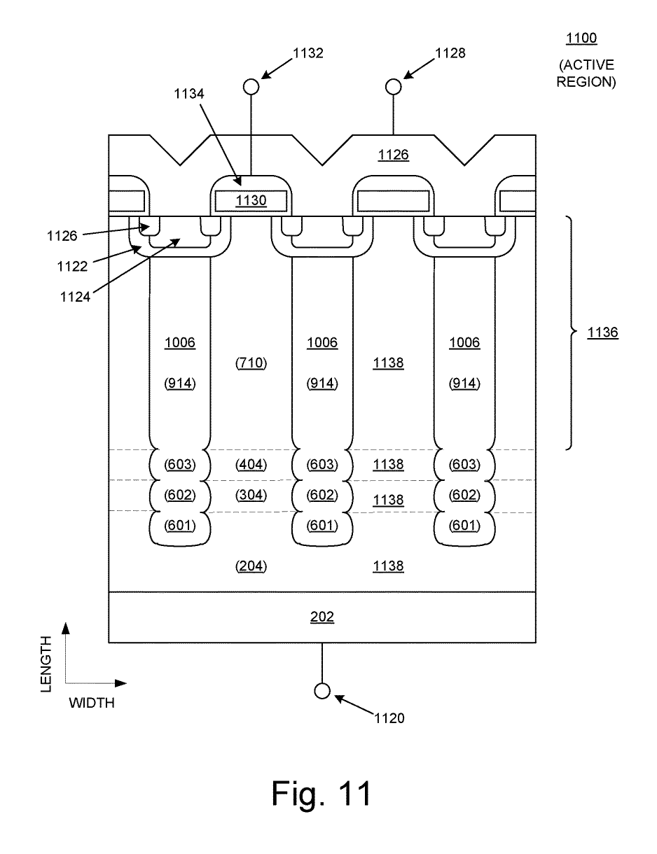

FIG. 1 is a flowchart 100 of a method for fabricating a device (e.g., the device 1100 of FIG. 11) in an embodiment according to the present invention. Operations described as separate blocks may be combined and performed in the same process step (that is, in the same time interval, after the preceding process step and before the next process step). Furthermore, fabrication processes and steps may be performed along with the processes and steps discussed herein; that is, there may be a number of process steps before, in between and/or after the steps shown and described herein. Importantly, embodiments according to the present invention can be implemented in conjunction with these other (perhaps conventional) processes and steps without significantly perturbing them. Generally speaking, embodiments according to the present invention can replace portions of a conventional process without significantly affecting peripheral processes and steps.

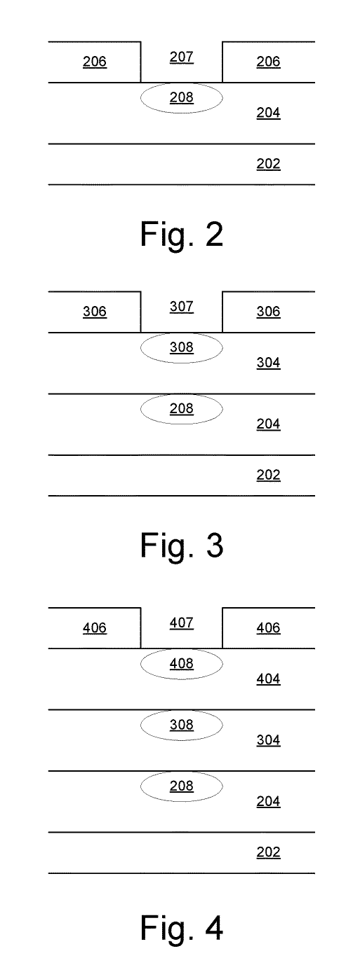

In block 1 of FIG. 1, with reference also to FIG. 2, an ‘n−’ layer 204 is formed over an ‘n+’ substrate layer 202. Generally speaking, the layer 202 includes a first concentration of first-type dopant, and the layer 204 includes a second concentration of first-type dopant. In one embodiment, the two concentrations are different and, in one such embodiment, the second concentration is less than the first concentration.

Photoresist 206 is selectively deposited over the layer 204 such that a gap 207 is formed. A portion of the layer 204 is exposed through the gap, while other portions of the layer 204 are covered by the photoresist 206. Any number of such gaps may be formed in this manner.

After the gap 207 is formed, ‘p’ dopant is implanted into the layer 204 to form ‘p’ region 208. Generally speaking, a region of second-type dopant is formed in the layer 204 of first-type dopant. Any number of such regions may be formed (a region per gap). The photoresist 206 is then removed.

In block 2 of FIG. 1, with reference also to FIG. 3, in one embodiment, the steps just described are essentially repeated. More specifically, an ‘n−’ layer 304 is formed over the layer 204. Photoresist 306 is deposited to form a gap 307 that exposes a portion of the layer 304. Significantly, the gap 307 is aligned with the ‘p’ region 208. After the gap 307 is formed, ‘p’ dopant is implanted into the layer 304 to form ‘p’ region 308. The photoresist 306 is then removed.

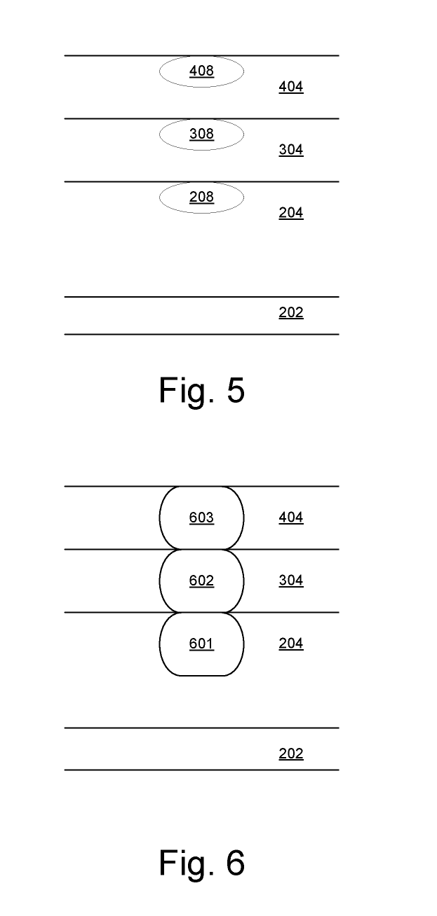

With reference next to FIG. 4, in one embodiment, the steps are essentially repeated again. More specifically, an ‘n−’ layer 404 is formed over the layer 304. Photoresist 406 is deposited to form a gap 407 that exposes a portion of the layer 404. Significantly, the gap 407 is aligned with the ‘p’ region 308. After the gap 407 is formed, ‘p’ dopant is implanted into the layer 404 to form ‘p’ region 408. The photoresist 406 is then removed, resulting in the structure of FIG. 5.

As will be seen from the discussion to follow, the steps just described are part of a fabrication process that can achieve high aspect ratio columns (which may be referred to herein as composite trench and implant columns) in MISFET devices such as SJ MOSFETs. Any number of aligned ‘p’ regions (e.g., the regions 208, 308, or 408) can be formed as just described, depending on the aspect ratio that is desired. As described in detail below, the regions are thermally diffused to form larger volumes that are in contact with each other, and then a trench is formed and filled with ‘p’ dopant to form a column that is in contact with the uppermost volume. Thus, the greater the number of ‘p’ dopant regions formed, the higher the aspect ratio of the composite trench and implant column. The example described herein uses three such regions, but as just mentioned, the present invention is not so limited.

FIG. 5 illustrates three aligned regions 208, 308, and 408 of ‘p’ dopant. In block 3 of FIG. 1, with reference also to FIG. 6, the regions 208, 308, and 408 are thermally diffused, thereby forming the volumes 601, 602, and 603. Significantly, the volumes 601, 602, and 603 are aligned with each other, and are also in contact with their neighbors (e.g., the volume 602 is contact with both volumes 601 and 603), forming a continuous composite column of ‘p’ dopant. The volumes 601, 602, and 603 have substantially the same width, measured at their widest points. That is, there may be some deviation in their respective widths, but their widths are close enough that, collectively, they form a columnar region.

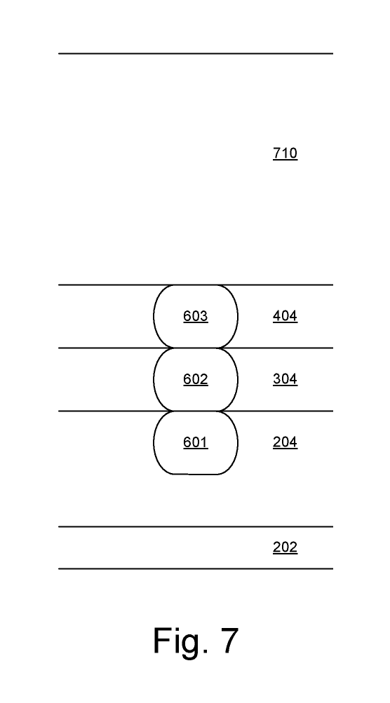

In block 4 of FIG. 1, with reference also to FIG. 7, another ‘n+’ layer 710 is formed (e.g., deposited or grown) over the structure shown in FIG. 6. Generally speaking, a layer 710 of first-type dopant is formed over the layer 404 of first-type dopant. The layer 710 includes a first concentration of first-type dopant, and the layer 404 includes a second concentration of first-type dopant. In one embodiment, the two concentrations are different and, in one such embodiment, the second concentration is less than the first concentration.

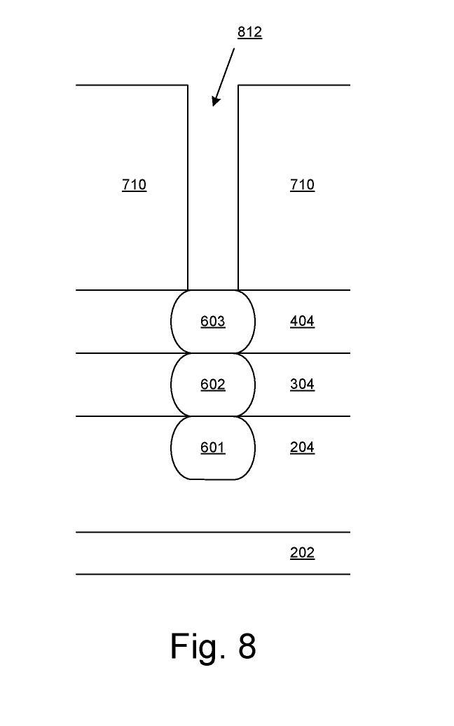

In block 5 of FIG. 1, with reference also to FIG. 8, a trench 812 is formed in the layer 710. The trench 812 can be etched, for example, using known techniques. Significantly, the trench 812 is aligned with the volumes 601, 602, and 603. Furthermore, the trench 812 extends through the layer 710 to expose the uppermost volume 603; that is, the trench 812 creates an opening that is in contact with the volume 603. In one embodiment, the trench 812 has substantially the same width as the volumes 601, 602, and 603. That is, there may be some deviation in width, but that deviation is small enough so that the trench 812 (when filled) and the volumes 601, 602, and 603, taken together, form a columnar region.

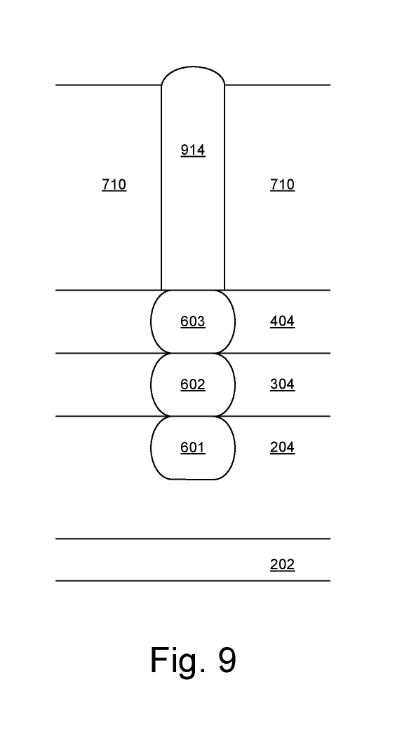

In block 6 of FIG. 1, with reference also to FIG. 9, the trench 812 is filled with ‘p’ dopant to form a column 914. The depth/length and width of the trench 812 are such that the ‘p’ dopant filling the trench is evenly distributed within the trench. In other words, the aspect ratio of the trench 812 can be chosen by design so that the ‘p’ dopant is not occluded or otherwise prevented from reaching the deepest parts of the trench.

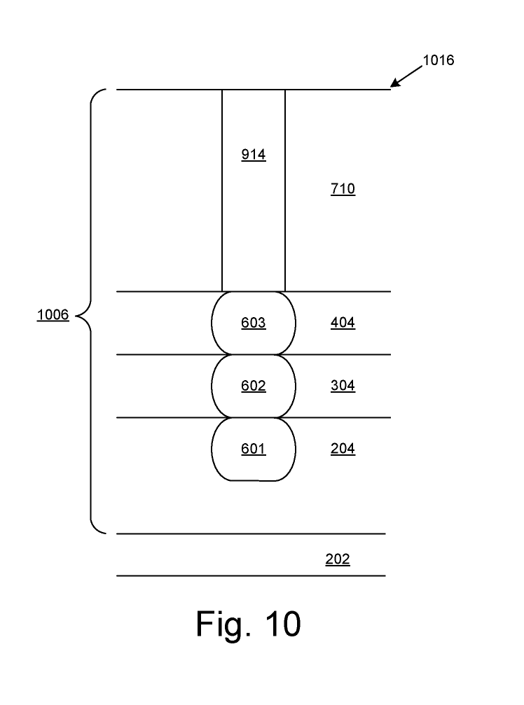

The dopant may extend above the top of the trench 812 at this point. Accordingly, in block 7 of FIG. 1, the upper surface of the structure is polished, oxide formed on the upper surface may be stripped, and the surface polished again (e.g., using chemical-mechanical planarization (CMP) polishing) to form a flat surface 1016 across the layer 710 and column 914, as shown in FIG. 10.

In this manner, a composite trench and implant column 1006 (which may be referred to simply as a composite column) is formed. In the example of FIGS. 1-10, the composite column 1006 includes the column 914 and the volumes 601, 602, and 603. The aspect ratio of the composite column 1006 is greater than the aspect ratio of just the column 914.

In block 8 of FIG. 1, with reference also to FIG. 11, other elements of a semiconductor device 1100 (e.g., a MISFET, such as an SJ MOSFET) are formed using known techniques.

In the FIG. 11 embodiment, the device 1100 includes a drain electrode 1120 on the bottom surface of the substrate 202. In the FIG. 11 embodiment, there is a ‘p’ base region 1122 at the top of each of the composite columns 1006 (in the orientation of FIG. 11). There may also be a ‘p+’ contact region 1124 and an ‘n+’ source region 1126 at each of the columns 1006, as shown.

In the FIG. 11 embodiment, a layer of source metal 1126 is coupled to a source electrode 1128, and a gate structure 1130 is coupled to a gate electrode 1132. The gate structure 1130 is separated from its neighboring elements and structures by an isolation layer 1134. One end of the trench 914 (the composite column 1006) is coupled to a contact (contact region 1124) to the source metal layer 1126, and the other end of that trench/composite column abuts the uppermost volume 603.

The layer of the device 1100 above the layers 204, 304, and 404 and below the source metal layer 1126 may be referred to as the epitaxial layer 1136. The epitaxial layer 1136 may include elements and structures instead of or in addition to those shown and described.

Collectively, the layers 204, 304, 404, and 710 may be referred to as ‘n’ region 1138. The p-type composite columns 1006 and the ‘n’ region 1138 form what is known as a super junction. The composite columns 1006 and the region 1138 are located within the active region of the device 1100. A termination region or termination regions (not shown) are disposed along the edges of the device 1100, around the active region.

The device 1100 may include elements and structures instead of or in addition to those shown and described.

Thus, in embodiments according to the present invention, a semiconductor device includes: a substrate (e.g., 202) of first-type dopant; a first region (e.g., 1138) of first-type dopant adjacent said substrate; and second regions (e.g., 1006) formed in the first region, where each of the second regions includes a trench (e.g., 812) filled with a second-type dopant (forming a column 914), and each of the trenches abuts a respective first volume (e.g., 603) of second-type dopant implanted in the first-type dopant between the trench and the substrate. Each of the first volumes may abut a respective second volume (e.g., 602) of second-type dopant also implanted in the first type-dopant between a respective first volume and the substrate. The first region (e.g., 1138) includes a first layer (e.g., 710) of first-type dopant adjacent to a second layer (e.g., 404) of first-type dopant, wherein each trench (e.g., 812, 914) is bounded by the second layer and each first volume (e.g., 603) is in the first layer.

Also, in embodiments according to the present invention, a semiconductor device includes: a substrate (e.g., 202) of a first concentration of first-type dopant; a first layer (e.g., 404), formed over the substrate layer, of a second concentration of the first-type dopant, where the second concentration is different from the first concentration; a first volume (e.g., 603) of second-type dopant formed in the first layer; and a columnar region (e.g., 914) of second-type dopant in contact with and extending longitudinally from the first volume, where the first volume is between the columnar region and the substrate layer. The columnar region is within a second layer (e.g., 710) of first-type dopant that is adjacent to the first layer. The first volume may abut a second volume (e.g., 602) of second-type dopant implanted in the first type-dopant (e.g., in the layer 304) between the first volume and the substrate layer.

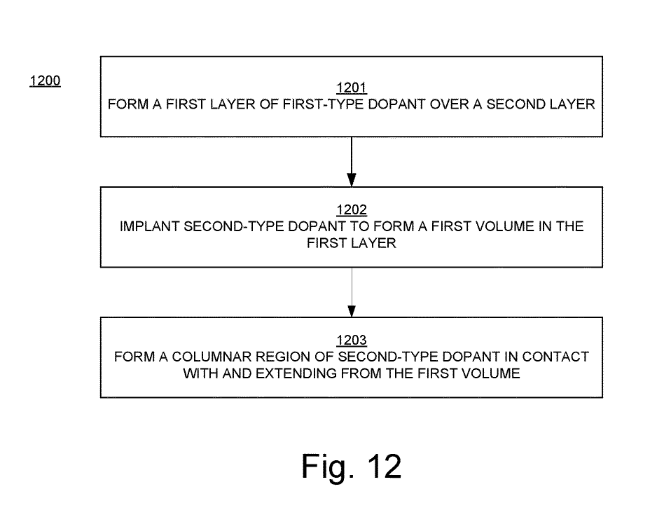

FIG. 12 is a flowchart 1200 of a method for fabricating a semiconductor device (e.g., the device 1100 of FIG. 11) in an embodiment according to the present invention.

In block 1201, with reference also to FIGS. 2, 3, and 4, a first layer of first-type dopant is formed over a second layer (e.g., the layer 404 is formed over the layer 304, or the layer 304 is formed over the layer 204, or the layer 204 is formed over the layer 202).

In block 1202 of FIG. 12, with reference also to FIG. 6, second-type dopant is implanted to form a first volume in the first layer (e.g., the volume 603 in the layer 404).

In block 1203 of FIG. 12, with reference also to FIG. 9, a columnar region of second-type dopant is formed in contact with and extending from the first volume (e.g., the column 914 is in contact with and extends from the volume 603).

In one embodiment, prior to forming the first layer (e.g., the layer 404) over the second layer (e.g., the layer 304) in block 1202, the second layer is formed over a third layer (e.g., the layer 204). In such an embodiment, prior to forming the first layer (e.g., the layer 404) over the second layer (e.g., the layer 304), second-type dopant is implanted to form a second volume (e.g., the volume 602) in the second layer, where the first volume when subsequently formed is aligned between the second volume and the columnar region.

Similarly, in one embodiment, prior to forming the first layer (e.g., the layer 404) over the second layer (e.g., the layer 304), and prior to forming the second layer (e.g., the layer 304) over the third layer (e.g., the layer 204), the third layer is formed over a fourth layer (e.g., the layer 202). In such an embodiment, prior to forming the first layer over the second layer, and prior to forming the second layer over the third layer, second-type dopant is implanted to form a third volume (e.g., the volume 601) in the third layer, where the first and second volumes, when subsequently formed, are aligned between the third volume and the columnar region.

In summary, masked ‘p’ implants and ‘n’ layer growth are combined one or more times along with thermal drives to form ‘p’ volumes in the ‘n’ layers. An epitaxial layer is then deposited (grown), and then a trench is etched and filed with ‘p’ dopant. The upper trench portion is designed to connect with the lower volumes already formed so that a continuous composite trench and implant ‘p’ column is formed. This will lead to a vertical ‘p’ region that will be a combination of ‘p’ volumes essentially stacked one over the other and the ‘p’ filled trench.

The smooth junction realized because of the upper ‘p’ filled trench region results in higher breakdown and also leads to improved unclamped inductive switching (UIS) ruggedness. The breakdown voltage of this structure is scalable to higher voltages by either increasing the number of ‘p’ volumes and/or by increasing the depth of the ‘p’ filled trenches. In simulations, increasing the depth/length of the ‘p’ filled trench from 18.5 μm to 24.5 μm (with three ‘p’ volumes) increased breakdown voltage from about 670 volts to about 750 volts. Simulations also show that increasing the number of ‘p’ volumes from three to six (with a trench depth of 18.5 μm) increased breakdown voltage from about 670 volts to about 982 volts. Increasing trench depth will increase the aspect ratio, but it has the advantage that it will improve UIS ruggedness by pushing impact ionization into the bulk away from the surface and providing a direct path for the holes to the contact away from the bipolar region inherent in a MISFET.

Because of inherent voids in the filled trench, the reverse recovery charge (Qrr) of the MISFET will be lower. Also, the thermal cycle experienced by the filled trench can be significantly reduced so that there will be less thermal diffusion of dopant from the trench region into the surrounding ‘n’ epitaxial layer. This will result in decreased specific on-resistance.

The combination of the upper, smooth-sided ‘p’ region with the relatively uneven (rippled) ‘p’ volume portion provides an extra degree of freedom to shape the electrical field in such a way that high impact ionization occurs at the bottom portion of the composite trench and implant column.

Embodiments of MISFET devices, including SJ power MOSFET devices, are thus described. The features described herein can be used in low voltage devices as well as high voltage devices as an alternative to split-gate, dual-trench, and other conventional high voltage super junction devices.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A method of forming a semiconductor device, said method comprising:
forming a first layer over a second layer, said first layer comprising a first concentration of a first-type dopant;
implanting a second-type dopant to form a first volume in said first layer; and
forming a columnar region comprising said second-type dopant in contact with and extending from said first volume.

2. The method of claim 1 further comprising, prior to said forming a first layer:
forming said second layer over a third layer; and
implanting said second-type dopant to form a second volume in said second layer, wherein said first volume when subsequently formed is aligned between said second volume and said columnar region.

3. The method of claim 1 wherein said forming said columnar region comprises, after said forming a first layer and forming said first volume:
forming a third layer comprising a second concentration of said first-type dopant over said first layer, wherein said first concentration is less than said second concentration;
forming a trench through said third layer, exposing said first volume; and
filling said trench with said second-type dopant.

4. The method of claim 1 wherein said first-type dopant comprises n-type dopant, and said second-type dopant comprises p-type dopant.

5. The method of claim 1 wherein said first volume and said columnar region have substantially the same width measured at their widest points.

6. A metal-insulator-semiconductor field-effect transistor (MISFET) fabricated by the method of claim 1.

7. The method of claim 1 wherein the semiconductor device is formed on a substrate comprising a third concentration of said first-type dopant, wherein said first concentration is less than said third concentration.
